(19) United States
(12) Patent Application Publication
(10) Pub. No.: US 2023/0420298 A1
(43) Pub. Date: Dec. 28, 2023

(54) MULTI-PATHWAY ROUTING VIA THROUGH HOLE

(71) Applicant: Intel Corporation, Santa Clara, CA (US)

(72) Inventors: Suddhasattwa Nad, Chandler, AZ (US); Cemil Serdar Geyik, Gilbert, AZ (US); Jiwei Sun, Chandler, AZ (US); Jason Steill, Phoenix, AZ (US)

(21) Appl. No.: 17/851,999

(22) Filed: Jun. 28, 2022

(51) Int. Cl. H01L 21/768; H01L 23/48; H01L 23/00; H01L 25/065

(52) U.S. Cl. CPC H01L 21/76898; H01L 23/481; H01L 24/16; H01L 2225/06541; H01L 2224/13025; H01L 2224/0401; H01L 25/0655

(57) ABSTRACT

An electronic device comprises a substrate layer comprising a first side and an opposing second side, a through hole passing through the substrate layer between the first side and the second side, a first electrical pathway passing from a first position on the first side of the substrate layer, through a first portion of the through hole, to a first corresponding position on the second side of the substrate layer, a second electrical pathway passing from a second position on the first side of the substrate layer, through a second portion of the through hole, to a corresponding second position on the second side of the substrate layer, and an insulation layer between the first electrical pathway and the second electrical pathway within the through hole, wherein the insulation layer electrically isolates the first electrical pathway from the second electrical pathway.

### TECHNICAL FIELD

Embodiments described herein generally relate to electrical connections in electronic devices. More specifically, embodiments described herein relate to an improved routing of multiple pathways from a first side of a substrate layer to an opposing second side of the substrate layer.

### BACKGROUND

Electrical devices may include electrically insulating substrates upon which are fabricated various electronic structures to provide the functionality for the device. It is often desired to provide one or more electrical pathways between the opposing sides of the substrate, for example to provide a pathway for electrical signals to pass from one or more devices on a first side to one or more devices on a second side of the substrate or vice versa, or to electrically ground one or more structures on a first side of the substrate to one or more structures on the opposing second side, or for an electrical power supply to pass from the first side to the second side or vice versa. Most electrical devices include a large array of these electrical pathways, which typically must be carefully designed and positioned so as to avoid cross-talk and for desired impedance matching between different pathways that are close to one another.

### BRIEF DESCRIPTION OF THE DRAWINGS

FIG. 1 is a cross-sectional elevation view of a portion of an example electronic device with multiple electrical pathways routed through a common through hole, in accordance with some example embodiments.

FIG. 2 is a cross-sectional plan view of the example electronic device of FIG. 1 taken along line 2-2 in FIG. 1, in accordance with some example embodiments.

FIG. 3 is a cross-sectional elevation view of a portion of another example electronic device with multiple electrical pathways routed through a common through hole, in accordance with some example embodiments.

FIG. 4 is a cross-sectional plan view of the example electronic device of FIG. 3 taken along line 4-4 in FIG. 3, in accordance with some example embodiments.

FIG. 5 is a cross-sectional elevation view of an example electronic package that can include the multi-pathway routing configurations of FIGS. 1-4, in accordance with some example embodiments.

FIG. 6 is a flow diagram showing an example method of manufacturing an electronic device that includes multiple electrical pathways routed through a common through hole, in accordance with some example embodiments.

FIGS. 7A-7L show elevation and plan views of various steps of a method of forming multiple electrical pathways through a common through hole, in accordance with some example embodiments.

FIG. 8A is a cross-sectional plan view of a conventional single-ended interconnect array with signal pathways and ground pathways each being passed through individual dedicated through holes, in accordance with some example embodiments.

FIG. 8B is a cross-sectional plan view of a comparative single-ended interconnect array with signal and ground pathways being routed through a common through hole, in accordance with some example embodiments.

FIG. 9 is a cross-sectional plan view of the signal and ground pathways within the common through hole in the comparative single-ended interconnect array of FIG. 7B, in accordance with some example embodiments.

FIG. 10A is a cross-sectional plan view of a conventional differential signaling configuration with a pair of signal pathways each being passed through an individual dedicated signal through hole that are surrounded by a plurality of ground pathways each being passed through individual dedicated ground through holes, in accordance with some example embodiments.

FIG. 10B is a cross-sectional plan view of a comparative differential signaling configuration with a pair of multi-pathway through holes each including a signal pathway and a ground pathway passing through the same through hole, in accordance with some example embodiments.

FIG. 11 is a system diagram depicting a system that may incorporate the example multi-pathway through hole and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present disclosure, in one or more embodiments, relates to routing multiple electrical pathways through the same through hole in a substrate layer so as to route multiple pathways more efficiently through the substrate layer. As designs of electronic devices have utilized progressively larger numbers of electrical pathways through substrate layers per unit area of the substrate layer, they have required a correspondingly larger number of ground pathways for the purpose of impedance matching and cross-talk mitigation. In conventional designs, this has required drilling more and more through holes through substrate layers (e.g., a larger number for the signal pathways and a larger number for the ground pathways), which has resulted in design and other build-up challenges.

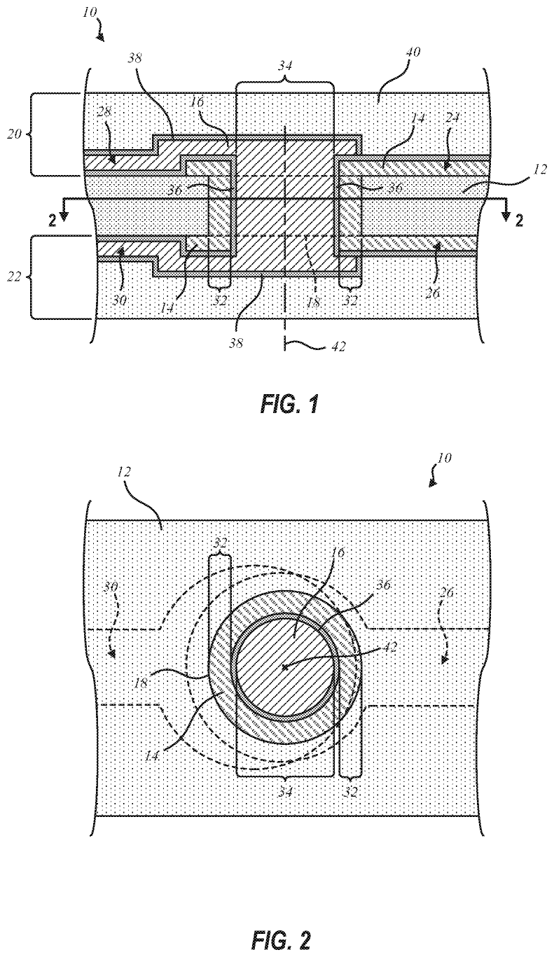

FIGS. 1 and 2 illustrate an electrical routing configuration for use in an electronic device 10 that provides a solution for these problems by routing multiple electrical pathways through the same through hole in a substrate within the electronic device 10. FIG. 1 shows a side cross-sectional view of the electronic device 10, while FIG. 2 shows a top cross-sectional view taken along line 2-2 in FIG. 1. The electronic device 10 includes a substrate 12 with at least two electrical pathways 14 and 16 passing through the same through hole 18 in the substrate 12 so that each electrical pathway 14, 16 provides an electrically conducting pathway passing from a first side 20 of the substrate 12 (e.g., the top side 20 of the substrate 12 in the view shown in FIG. 1) to an opposing second side 22 of the substrate 12 (e.g., the bottom side of the substrate 12 in the view shown in FIG. 1). For ease of distinguishing between the structures that make up the electrical pathways 14, 16, in each view of the Figures, a first cross-hatching will be used for the first electrical pathway 14 (i.e., with parallel cross-hatching lines extending from the top left toward the bottom right in the views of the Figures) and similarly a different, second cross-hatching will be used for the second electrical pathway 16 (i.e., with parallel cross-hatching lines extending from the top right toward the bottom left in the vies of the Figures, which is 90° different from the first cross-hatching of the first electrical pathway 14).

As will be appreciated by those having skill in the art, FIG. 1 shows a view of a small portion of the electronic device 10, focusing on the electrical pathways 14, 16 passing from the first side 20 to the second side 22 through the through hole 18. Those having skill in the art will appreciate that the electronic devices described and shown herein, including the electronic device 10 of FIGS. 1 and 2, can include other structures, including, but not limited to, one or more devices or structures electrically connected to each electrical pathway 14, 16 on the first side 20 and second side 22 of the substrate 12.

Each electrical pathway 14, 16 is formed from an electrically conductive material, such as a metal or other conductor. Examples of materials that can be used to form each of the electrical pathways 14, 16 include, but are not limited to: copper, silver, gold, tin, aluminum, titanium, tungsten, and nickel.

Each electrical pathway 14, 16 can be configured to serve a specified purpose in the electronic device 10. For example, one or both of the pathways 14, 16 can be configured to carry an electrical signal from the first side 20 of the substrate 12 to the second side 22 or vice versa, or both. Alternatively, or in addition, one or both of the pathways 14, 16 can be configured to be an electrical ground within the electronic device 10, e.g., grounding a structure on the first side 20 to another structure on the second side 22. In yet another example, one or both of the electrical pathways 14, 16 can be configured to carry electrical power from the first side 20 to the second side 22 of the substrate 12, or vice versa, e.g., to power an electronic component of the electronic device 10.

As can be seen in FIG. 1 in particular, each pathway 14, 16 provides a conductive route between a specified position on the first side 20 of the substrate 12 to a corresponding specified position on the second side 22 of the substrate 12, wherein the conductive route passes through a corresponding portion of the through hole 18. For example, the first electrical pathway 14 provides an electrically conductive route from a first specified position 24 on the first side 20 of the substrate 12 (e.g., to the right of the through hole 18 on the top side 20 in the view shown in FIG. 1) to a first corresponding specified position 26 on the second side 22 of the substrate 12 (e.g., to the right of the through hole 18 on the bottom side 22 in the view shown in FIG. 1). Similarly, in an example, the second electrical pathway 16 provides an electrically conductive route from a second specified position 28 on the first side 20 of the substrate 12 (e.g., to the left of the through hole 18 on the top side 20 of the substrate 12 in the view shown in FIG. 1) to a second corresponding specified position 30 on the second side 22 of the substrate 12 (e.g., to the left of the through hole 18 on the bottom side 22 of the substrate 12 in the view shown in FIG. 1).

In order to accommodate both the first and second pathways 14, 16 through the same through hole 18, each electrical pathway 14, 16 is designated its own specified portion of the through hole 18 through which to pass between the first and second sides 20, 22 of the substrate 12. For example, the first electrical pathway 14 passes through a first specified portion 32 of the through hole 18 while the second electrical pathway 16 passes through a second specified portion 34 of the through hole 18.

Because the two electrical pathways 14, 16 are configured to be separate and independent pathways, the electronic device 10 can also include an electrical insulation layer 36 located between the pathways 14 and 16. The insulation layer 36 comprises a non-conductive material that electrically isolates the first pathway 14 from the second pathway 16. Examples of non-conducting materials that can be used to form the insulation layer 36 include, but are not limited to: silicon nitride (SiNₓ, e.g., Si₃N₄), silicon oxynitride (SiOₓN_{y}, e.g., Si₂N₂O), silicon dioxide (SiO₂), a carbon-doped oxide (CDO), an organic dielectric, an organic polymer, a fluorine-doped silicon dioxide, or combinations or derivatives thereof. In an example, the electronic device 10 can also include a second insulation layer 38 around the outside of the second pathway 16, e.g., to isolate the second pathway 16 from other structures of the device 10. Also, in an example, the electronic device 10 can include a build-up layer 40 that is deposited over the top of at least a portion of each of the electrical pathways 14, 16, e.g., for the formation of other structures of the device 10. In an example where the electronic device 10 is a central processing unit or other processing device, the build-up layer 40 can be an Ajinomoto build-up film (“ABF”), as will be appreciated by those having skill in the art. Examples of materials that can be used to form the build-up layer 40 include, but are not limited to, organic polymers (such as an epoxy or polyimide based polymer) with or without inorganic filler material (e.g., silica-based filler and the like), or combinations thereof.

The present disclosure is not limited to any particular positioning of each specified portion 32, 34 of the through hole 18 through which the electrical pathways 14, 16 pass. For example, as shown in FIGS. 1 and 2, the first specified portion 32 and the second specified portion 34 can be coaxially positioned, e.g., concentric about a central axis 42 of the through hole 18, with one of the specified portions 32, 34 being centrally located axially within the other of the specified portions 32, 34. In the example shown in FIGS. 1 and 2, the first specified portion 32 (i.e., through which the first pathway 14 passes) is located around the outer circumference of the through hole 18, while the second specified portion 34 (i.e., through which the second pathway 16 passes) is at a central position proximate to the axis 42. Those having skill in the art will appreciate that the first and second specified portions 32, 34 of the through hole 18 could be reversed from that which is shown in FIGS. 1 and 2, e.g., with the first specified portion 32 being centrally located proximate to the axis 42 and the second specified portion 34 being located around the outer circumference of the through hole 18, without varying from the scope of the present disclosure.

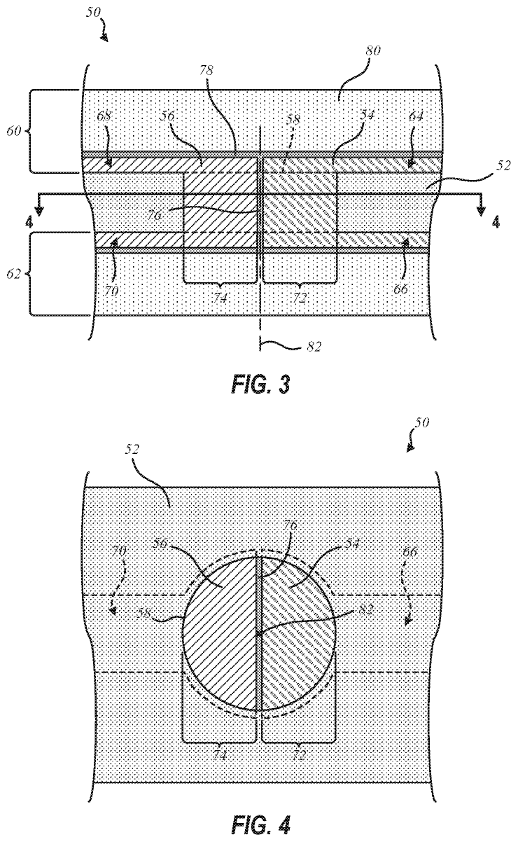

FIGS. 3 and 4 depict another example electronic device 50 that includes different positions for the specified portions of the through hole through which the electrical pathways pass. FIG. 3 shows a side cross-sectional view of the electronic device 50, while FIG. 4 shows a top cross-sectional view taken along line 4-4 in FIG. 3. The electronic device 50 is similar to the electronic device 10 of FIGS. 1 and 2. For example, the electronic device 50 also includes a substrate 52 with at least two electrical pathways 54 and 56 passing through the same through hole 58 in the substrate 52. The electrical pathways 54, 56 each provide an electrically conducting pathway passing from a first side 60 of the substrate 52 (e.g., the top side 60 of the substrate 52 in the view shown in FIG. 3) to an opposing second side 62 of the substrate 52 (e.g., the bottom side 62 of the substrate 52 in the view shown in FIG. 3). Like the electronic device 10 of FIGS. 1 and 2, the first pathway 54 of the electronic device 50 provides an electrically conductive route from a first specified position 64 on the first side 60 of the substrate 52 (e.g., to the right of the through hole 58 on the top side 60 in the view shown in FIG. 3) to a first corresponding specified position 66 on the second side 62 of the substrate 52 (e.g., to the right of the through hole 58 on the bottom side 62 in the view shown in FIG. 3). Similarly, the second electrical pathway 56 provides an electrically conductive route from a second specified position 68 on the first side 60 of the substrate 52 (e.g., to the left of the through hole 58 on the top side 60 in the view shown in FIG. 3) to a second corresponding specified position 70 on the second side 62 of the substrate 52 (e.g., to the left of the through hole 58 on the bottom side 62 in the view shown in FIG. 3). The material or materials that form each of the electrical pathways 54, 56 can be similar or identical to those used to form the electrical pathways 14, 16 in the electronic device 10 of FIGS. 1 and 2. Also, each electrical pathway 54, 56 can serve similar or identical functions to those described above for the electrical pathways 14, 16 in the electronic device 10.

However, as can be seen in FIGS. 3 and 4, the difference between the electronic device 50 and the electronic device 10 of FIGS. 1 and 2 is that instead of being concentric and coaxial within the through hole, as was the case with the pathways 14, 16 in the electronic device 10, the electrical pathways 54, 56 pass through opposing sides of the through hole 58. In other words, the first electrical pathway 54 passes through a first specified portion 72 of the through hole 58 that is on a first side of a central axis 82 of the through hole 58 (e.g., to the right of the axis 76 in the view shown in FIGS. 3 and 4) and the second electrical pathway 56 passes through a second specified portion 74 of the through hole 58 that is on an opposing second side of the central axis 76 (e.g., to the left of the axis 76 in the view shown in FIGS. 3 and 4). In the example best seen in FIG. 4, the first specified portion 72 takes up approximately half of the through hole 58 and the second specified portion 74 takes up approximately the other half of the through hole 58. Similar to the electronic device 10 of FIGS. 1 and 2, the electrical pathways 54, 56 can be isolated from one another by an insulation layer 76 between the first electrical pathway 54 and the second electrical pathway 56 within the through hole 58. An outer insulation layer 78 can also be included on each side 60, 62 of the pathways 54, 56 to electrically isolate the pathways 54, 56 from other structures of the electronic device 50. The insulation layers 76, 78 can be made from similar or identical materials to those described above for the insulation layers 36 and 38. The electronic device 50 can also include a build-up layer 80, which can be similar or identical to the build-up layer 40 of the electronic device 10.

As will be appreciated by those having skill in the art, the electronic device 10, 50 is not limited to having only two electrical pathways passing through the through hole 18, 58. Those having skill in the art could readily envision passing three or more electrical pathways through the through hole 18, 58, with each pathway having its own specified function within the electronic device 10, 50, without varying from the scope of the present disclosure. In such an example, each of the three or more pathways would take up its own specified portion of the through hole 18, 58. For example, if the electronic device was configured similar to the device 10, i.e., with the pathways being coaxial and concentric within the through hole 18, then a first of three pathways could pass through the outer circumference of the through hole 18, a second of the three pathways could pass through the center of the through hole 18 near its central axis 42, and a third of the three pathways could pass through an intermediate space located between the outer first pathway and the inner second pathway. Or, in an example configured similar to the electronic device 50, a first of the three pathways could pass through a left-side portion of the through hole 58, a second of the three pathways could pass through a right-side portion of the through hole 58, and a third of the three pathways could pass through a central portion of the through hole 58 between the left first pathway and the right second pathway. Like the examples shown in FIGS. 1-4, in examples with three or more pathways passing through the through hole 18, 58, adjacent pathways can be electrically isolated by insulation layers, similar to the insulation layers 36 and 76.

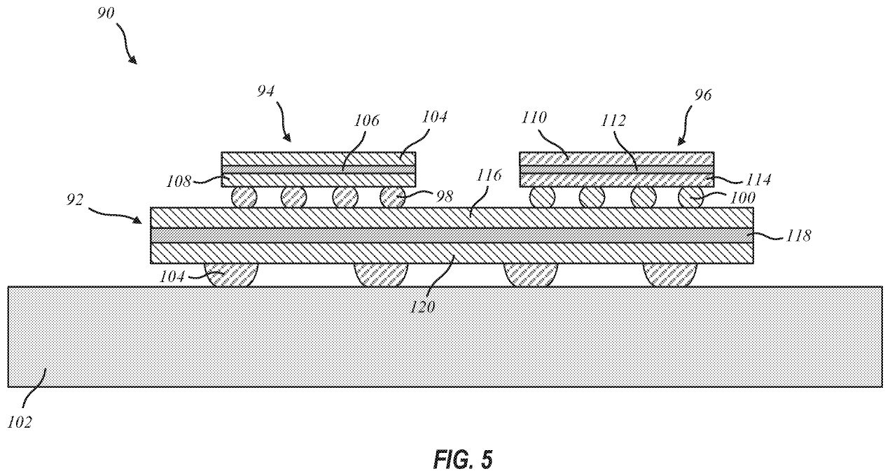

FIG. 5 is a schematic diagram of an electronic package 90 in which the multi-pathway routing configurations described above can be used. In an example, the electronic package 90 includes a package substrate 92 onto which can be mounted one or more semiconductor dies 94, %, such as with one or more die solder joints 98, 100. The package substrate 92 can be coupled to a circuit board 102, such as a mother board 102, with one or more solder joints 104. Each semiconductor die 94, % can include one or more layers, such as layers 104, 106, and 108 in the semiconductor die 94, and layers 110, 112, 114 in the semiconductor die %. Similarly, the package substrate 92 can include one or more layers, such as the layers 116, 118, 120. As will be appreciated by those having skill in the art, the various layers 104, 106, 108, 110, 112, 114, 116, 118, and 120 in the semiconductor dies 94, 96 and the package substrate 92 can be one of many types of structures common in semiconductor devices. For example, the package substrate 92 and the dies 94, % can each include active layers, routing layers, insulation layers, and the like.

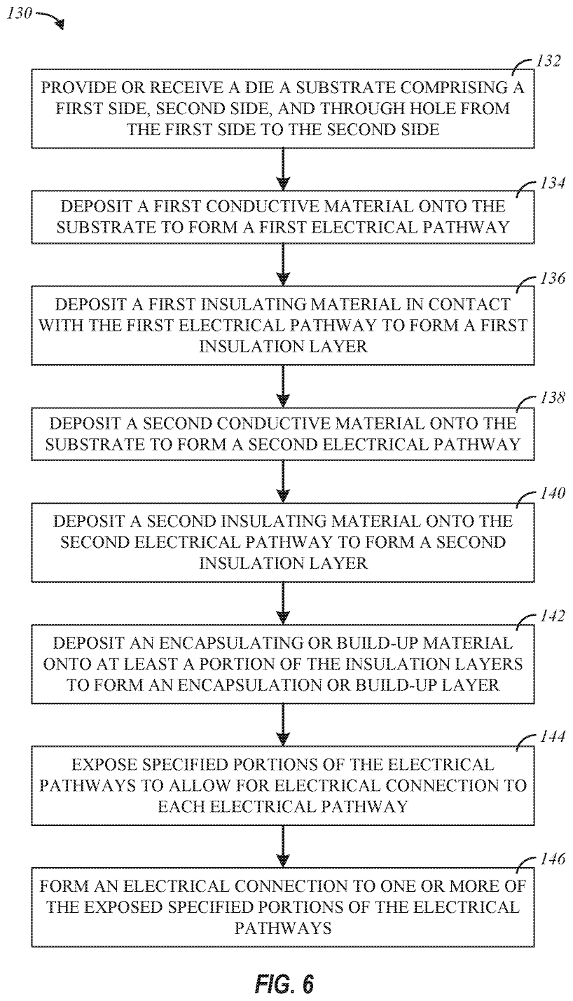

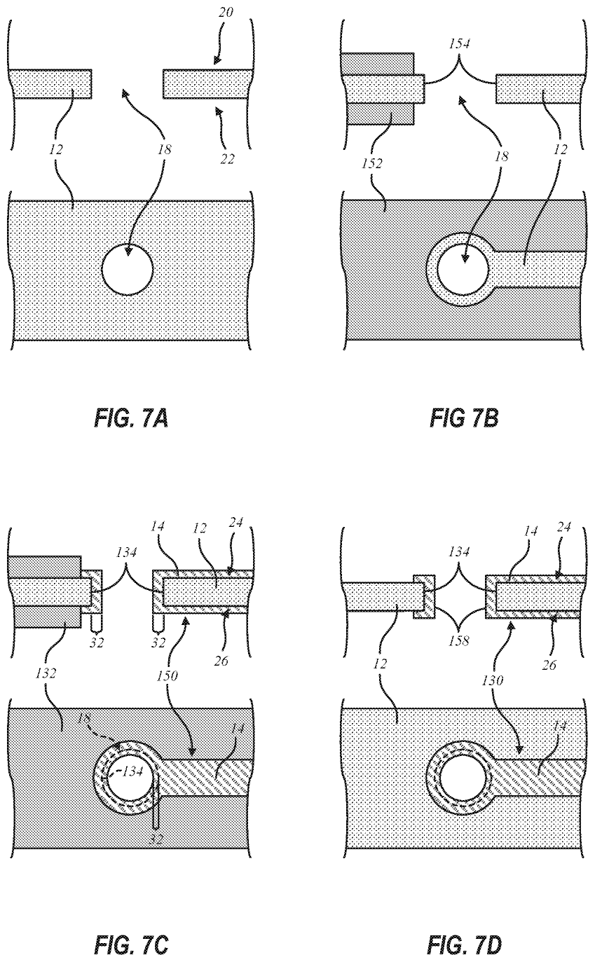

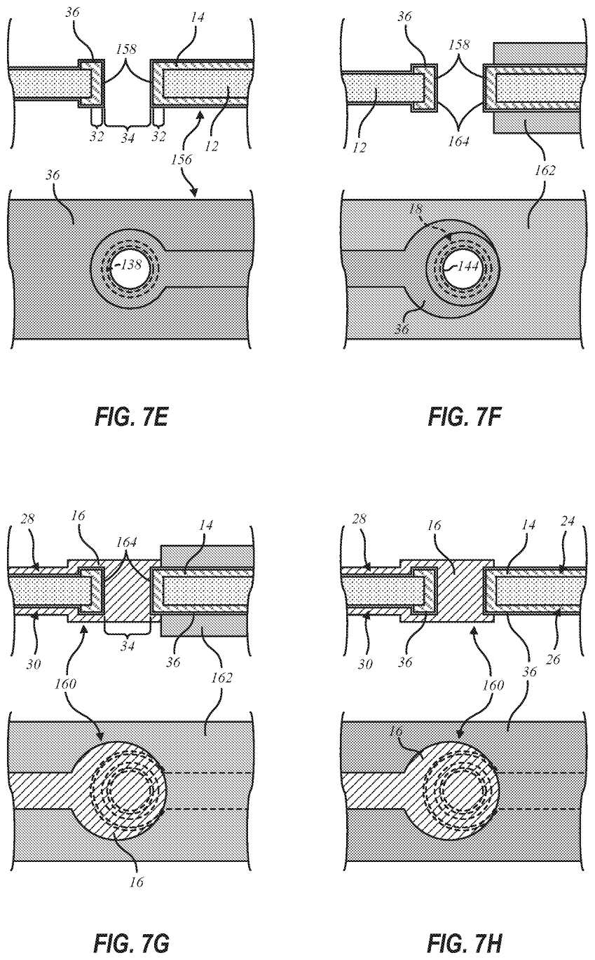

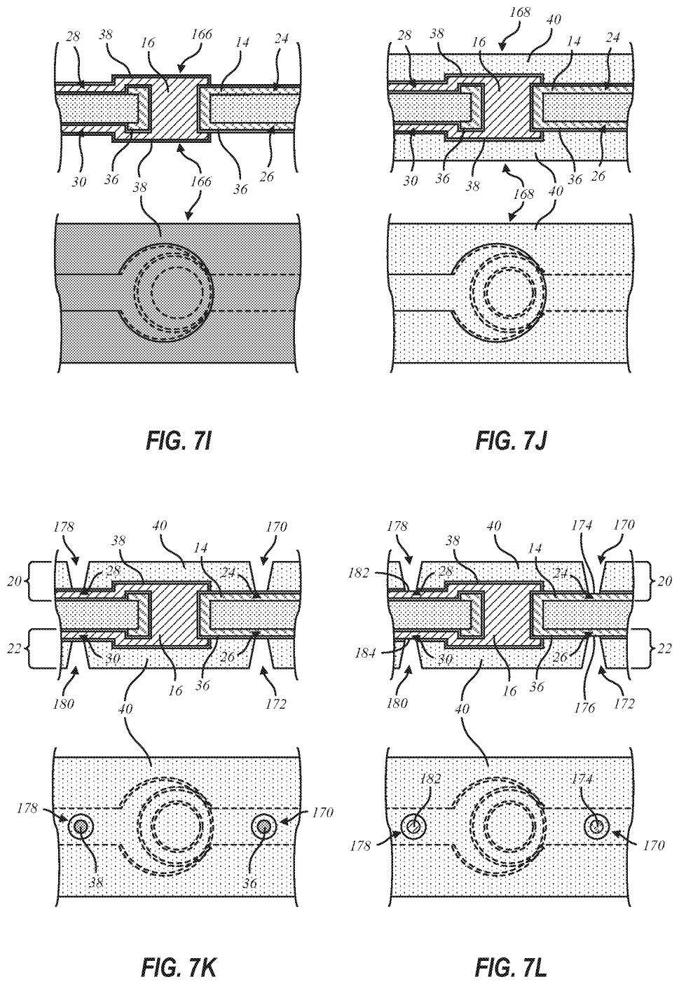

The multi-pathway electrical routing configurations described above with respect to FIGS. 1-4 or with respect to the method of FIG. 6 or the method steps of FIGS. 7A-7L show various examples of routing multiple electrical pathways. The routing configurations could be used, for example, for routing through any layer in the example package 90 of FIG. 5, such as in any of the layers 116, 118, 120 of the package substrate 92, any one or more of the layers 104, 106, 108 in the first semiconductor die 94, any one or more of the layers 110, 112, 114 of the second semiconductor die %, or in the circuit board 102. Those having skill in the art will appreciate that the routing configurations are not limited to use in any of the particular layers described above with respect to FIG. 5, but rather the layers of FIG. 5 are provided as examples of structures in which the multi-pathway routing configurations of the present disclosure can be implemented

FIG. 6 is a flow diagram of an example method 130 of fabricating a portion of an electronic device such as the electronic device 10 shown in FIGS. 1 and 2 or the electronic device 50 shown in FIGS. 3 and 4. FIGS. 7A-7L show a cross-sectional elevation view and a plan view of the electrical pathways 14, 16 as they are formed by the example method 130 of FIG. 6. In an example, the method 130 includes, at step 132, providing or receiving a substrate (such as the substrate 12), which includes a first side (such as the first side 20 of the substrate 12), an opposing second side (such as the second side 22 of the substrate 12), and a through hole passing through the substrate 12 from the first side 20 to the second side 22 (such as the through hole 18). FIG. 7A shows views of the substrate 12 that can be provided or received for step 132 of the method 130.

Next, at step 134, the method 130 includes depositing a first conductive material 150 onto the substrate 12 to form a first electrical pathway 14. In an example, the first electrical pathway 14, when formed, passes from a first position on the first side 20 of the substrate 12 (such as the first specified position 24), through a first portion of the through hole 18 (such as the first specified portion 32 of the through hole 18), to a first corresponding position on the second side 22 of the substrate 12 (such as the first corresponding specified position 26). Examples of materials that can be used as the first conductive material 150 are described above with respect to the first electrical pathway 14 in the electronic device 10 of FIGS. 1 and 2.

In an example, shown in FIGS. 7B-7D, depositing the first conductive material 150 to form the first electrical pathway 14 comprises forming a first resist 152 on the substrate 12 in a first specified pattern that corresponds to the desired shape of the first electrical pathway 14, e.g., such that the first resist 152 leaves exposed specified portions of the substrate 12 onto which are to be deposited the first conductive material 150, as shown in FIG. 7B. As can be seen in the example of FIG. 7B, and in particular in the plan view shown at the bottom of FIG. 7B, the first resist 152 leaves exposed a portion of the substrate 12 leading up to and surrounding the through hole 18.

After the first resist 152 is formed, the method 130 can include depositing the first conductive material 150, such as a conductive metal, onto the portions of the substrate 12 that are left exposed by the first resist 152, which forms the structure that will become the first electrical pathway 14, as shown in FIG. 7C. In an example, depositing the first conductive material 150 forms a layer of the conductive material 150 on the substrate 12, including on an interior bore surface 154 of the through hole 18, as shown in FIG. 7C, such that the deposited first conductive material 150 is deposited within a first portion of the through hole (such as the first specified portion 32 of the through hole 18). As a result, the deposited first conductive material 150 forms a conductive pathway 14 that forms a conductive route between one position on one side of the substrate and a corresponding position on the other side of the substrate (such as the first specified position 24 on the first side 20 of the substrate 12 and the first corresponding specified position 26 on the second side 22 of the substrate 12). In an example, the first conductive material 150 can be deposited by plating the first conductive material 150 onto the substrate 12. Finally, after the first electrical pathway 14 has been formed by depositing the first conductive material 150, the step of depositing the first conductive material to form the first electrical pathway 14 (step 134) can include removing the first resist 152 so that only the first conductive material 150 remains, as shown in FIG. 7D.

After the first conductive material 150 has been deposited to form the first electrical pathway 14 (step 134), the method 130 can include, at step 136, depositing a first insulating material 156 so that the first insulating material 156 is in contact with the first electrical pathway 14, which forms a first insulation layer (such as the insulation layer 36) that electrically isolates the first electrical pathway 14 from a second portion of the through hole (such as the second specified portion 34 of the through hole 18, which is separate from the first specified portion 32, e.g., so that the first specified portion 32 is electrically isolated from the second specified portion 34). FIG. 7E shows the intermediate structure that is formed after depositing the first insulating material 156 to form the first insulation layer 36. In an example, shown in FIG. 7E, depositing the first insulating material 156 to form the first insulation layer 36 includes depositing the first insulating material 156 onto an interior bore surface 158 of the first conductive material 150, e.g., so that the first electrical pathway 14 will be electrically isolated from the second specified portion 34 of the through hole 18. Depositing the first insulating material 156 (step 136) can also include depositing the first insulating material 156 onto other portions of the first conductive material 150, such as outer surfaces on either side 20, 22 of the substrate. As described below, in an example, a second conductive material will be deposited into the second specified portion 34 of the through hole 18 to form the second electrical pathway 16, and therefore depositing the first insulating material 156 onto the interior bore surface 158 of the first conductive material 150 can ensure that the first electrical pathway 14 is electrically isolated from the second electrical pathway 16. Examples of materials that can be used as the first insulating material 156 are described above with respect to the first insulation layer 36 in the electronic device 10 of FIGS. 1 and 2.

After the first insulation layer 36 has been formed by depositing the first insulating material 156 (step 136), the method 130 can include, at step 138, depositing a second conductive material 160 onto the substrate 12 to form a second electrical pathway (such as the second electrical pathway 16). In an example, the second electrical pathway 16, when formed, passes from a second position on the first side 20 of the substrate 12 (such as the second specified position 28), through a second portion of the through hole 18 (such as the second specified portion 34 of the through hole 18), to a second corresponding position on the second side 22 of the substrate 12 (such as the second corresponding specified position 30). As discussed above, the second conductive material 160 can be similar or identical to the first conductive material 150 or can be a different conductive material. Examples of materials that can be used as the second conductive material 160 are described above with respect to the second electrical pathway 16 in the electronic device 10 of FIGS. 1 and 2.

Depositing the second conductive material 160 onto the substrate 12 to form the second electrical pathway 16 (step 138) can be similar to the step of depositing the first conductive material 150 to form the first electrical pathway 14 (step 134), for example via the sub-steps shown in FIGS. 7F-7H. In an example, this includes forming a second resist 162 on the already formed structures (e.g., the substrate 12, the first electrical pathway 14, and the first insulation layer 36) in a second specified pattern that corresponds to the desired shape of the second electrical pathway 16, e.g., such that the second resist 162 leaves exposed specified portions of the substrate 12 and the first insulation layer 36 onto which are to be deposited the second conductive material 160, as shown in FIG. 7F. As can be seen in the example of FIG. 7F, and in particular in the plan view shown at the bottom of FIG. 7F, the second resist 162 leaves exposed a portion of the first insulation layer 36 leading up to and surrounding the general location of the through hole 18, including the second specified portion 34 of the through hole 18 that is currently unoccupied.

After the second resist 162 is formed, the method 130 can include depositing the second conductive material 160, such as a conductive metal, onto the portions of the structures that are left exposed by the second resist 162, which forms the structure that will become the second electrical pathway 16, as shown in FIG. 7G. In an example, depositing the second conductive material 160 forms a layer of the second conductive material 160 over a portion of the first insulation layer 36, including on an interior bore surface 164 of the first insulation layer 36 that is within the through hole 18, as shown in FIG. 7G, such that the deposited second conductive material 160 is deposited within a second portion of the through hole (such as the second specified portion 34). As a result, the deposited second conductive material 160 forms the second electrical pathway 16 that forms a conductive route between one position on one side of the substrate and a corresponding position on the other side of the substrate (such as the second specified position 28 on the first side 20 of the substrate 12 and the second corresponding specified position 30 on the second side 22 of the substrate 12). In an example, the second conductive material 160 can be deposited by plating the second conductive material 160 onto the first insulation layer 36. After the second electrical pathway 16 has been formed by depositing the second conductive material 160, the step of depositing the second conductive material to form the second electrical pathway 16 (step 138) can include removing the second resist 162 so that only the second conductive material 160 remains on the first insulation layer 36, as shown in FIG. 7H.

Next, the method 130 can include, at step 140, depositing a second insulating material 166 onto at least a portion of the second electrical pathway 16, which forms a second insulation layer (such as the second insulation layer 38), as shown in FIG. 7I. The second insulation layer 38 can electrically isolate the second electrical pathway 16 from other structures of the electronic device 10. In an example, the second insulation layer 38 is in contact with the first insulation layer 36 so that both electrical pathways 14, 16 are electrically isolated from each other and from other structures of the electronic device 10. As noted above, the second insulating material 166 can be similar or identical to the first insulating material 156. Examples of materials that can be used as the second insulating material 166 are described above with respect to the second insulation layer 38 in the electronic device 10 of FIGS. 1 and 2.

In an example, the method 130 can include, at step 142, depositing an encapsulating or build-up material 168 onto at least a portion of the first insulation layer 36, the second insulation layer 38, or both the first and second insulation layers 36 and 38, which forms an encapsulation layer or a build-up layer (such as the build-up layer 40 in the electronic device 10), as shown in FIG. 7J. Examples of materials that can be used as the encapsulating or build-up material 168 are described above with respect to the build-up layer 40 in the electronic device 10 of FIGS. 1 and 2.

Because both the insulation layers 36, 38 and the build-up layer 40 cover the conductive materials 150, 160 that form the electrical pathways 14, 16, in an example, the method 130 can include, at step 144, exposing specified portions of the electrical pathways 14, 16 to allow for electrical connection between each electrical pathway 14, 16 and one or more other structures. In an example, exposing the specified portions of the electrical pathways 14, 16 (step 144) includes forming one or more vias through one or more layers of the electronic device 10 such that one or more specified portions of the electrical pathways 14, 16 are exposed.

In an example, exposing the specified portions of the electrical pathways 14, 16 (step 144) can include exposing a first portion of the first electrical pathway 14 on the first side 20 of the substrate 12 (e.g., at or proximate to the first specified position 24 of the first electrical pathway 14) and exposing a second portion of the first electrical pathway 14 on the second side 22 of the substrate 12 (e.g., at or proximate to the first corresponding specified position 26 of the first electrical pathway 14) so that electrical connections can be made to the first electrical pathway 14 on the opposing sides 20, 22 of the substrate 12. In an example, this exposing of the different specified portions of the first electrical pathway 14 can include forming a first via 170 in the build-up layer 40 on the first side 20 of the substrate 12 at or proximate to the first specified position 24 and forming a second via 172 in the build-up layer 40 on the second side 22 of the substrate 12 at or proximate to the first corresponding specified position 26, as shown in FIG. 7K. Forming the vias 170, 172 through the build-up layer 40 includes removing material of the build-up layer 40 at the desired location of the vias 170, 172, which can include, but is not limited to, laser-drilling or acid-based or solvent-based etching. Exposing the specified portions of the first electrical pathway 14 can also include removing material of the first insulation layer 36 so that the vias 170, 172 pass through the first insulation layer 36 and expose an outer surface 174 of the first electrical pathway 14 on the first side 20 of the substrate (e.g., at or proximate to the first specified position 24) and/or expose an outer surface 176 of the first electrical pathway 14 on the second side 22 of the substrate 12 (e.g., at or proximate to the first corresponding specified position 26), as shown in FIG. 7L. Removing the material of the first insulation layer 36 can include, but is not limited to, plasma-based etching or wet chemical-based etching of the first insulating material.

Similarly, in an example, exposing the specified portions of the electrical pathways 14, 16 (step 144) can include exposing a first portion of the second electrical pathway 16 on the first side 20 of the substrate 12 (e.g., at or proximate to the second specified position 28 of the second electrical pathway 16) and exposing a second portion of the second electrical pathway 16 on the second side 22 of the substrate 12 (e.g., at or proximate to the second corresponding specified position 30 of the second electrical pathway 16) so that electrical connections can be made to the second electrical pathway 16 on the opposing sides 20, 22 of the substrate 12. This exposing of the different specified portions of the second electrical pathway 16 can be similar or identical to that described above for exposing the specified portions of the first electrical pathway 14. For example, it can include forming a first via 178 in the build-up layer 40 on the first side 20 of the substrate 12 at or proximate to the second specified position 28 and forming a second via 180 in the build-up layer 40 on the second side 22 of the substrate 12 at or proximate to the second corresponding specified position 30, as shown in FIG. 7K. e.g., by removing the material of the build-up layer 40 at the desired location of the vias 178, 180, followed by removing material of the second insulation layer 38 so that the vias 178, 180 pass through the second insulation layer 38 and expose an outer surface 182 of the second electrical pathway 16 on the first side 20 of the substrate (e.g., at or proximate to the second specified position 28) and/or expose an outer surface 184 of the second electrical pathway 16 on the second side 22 of the substrate 12 (e.g., at or proximate to the second corresponding specified position 30), as shown in FIG. 7L. Removing the material of the build-up layer 40 and the second insulation layer 38 to expose the surfaces 182, 184 of the second electrical pathway 16 can be similar or identical to that described above for removing the build-up layer 40 and the first insulation layer 36 to expose the surfaces 174, 176 of the first electrical pathway 14.

The method 130 can also include, at step 146, forming an electrical connection to one or more of the exposed specified portions of the electrical pathways 14, 16, such as by welding a conductor (e.g., a wire or lead) to an exposed specified portion of the first electrical pathway 14 or to an exposed specified portion of the second electrical pathway 16, or both (not shown in the Figures).

The routing of multiple electrical pathways through a common through hole, as described above with respect to the example electronic devices 10, 50 and the example method 130, provides advantages over conventional means of routing electrical pathways through a substrate, i.e., using a separate through hole for each electrical pathway. For example, the routing of the present disclosure can provide for significantly higher densities of electrical pathways through a substrate compared to conventional means of routing.

This advantage is particularly evident when looking at a specific use case of high-speed input/output pathways (also referred to hereinafter as “HSIO pathways” or simply as “HSIOs”) in computer processing or memory devices. Impedance matching and crosstalk management of HSIOs can result in signal pathways requiring a specified number of ground pathways. In conventional (e.g., one through hole for each pathway), the large number of signal and ground pathways for HSIO applications results in a large number of through holes through a core substrate and a relatively high density of the pathways within the processing or memory device. In contrast, the routing of a plurality of electrical pathways, such as a signal pathway and a ground pathway, through the same through hole can provide for significantly reduced substrate real estate being required for cross-substrate pathways.

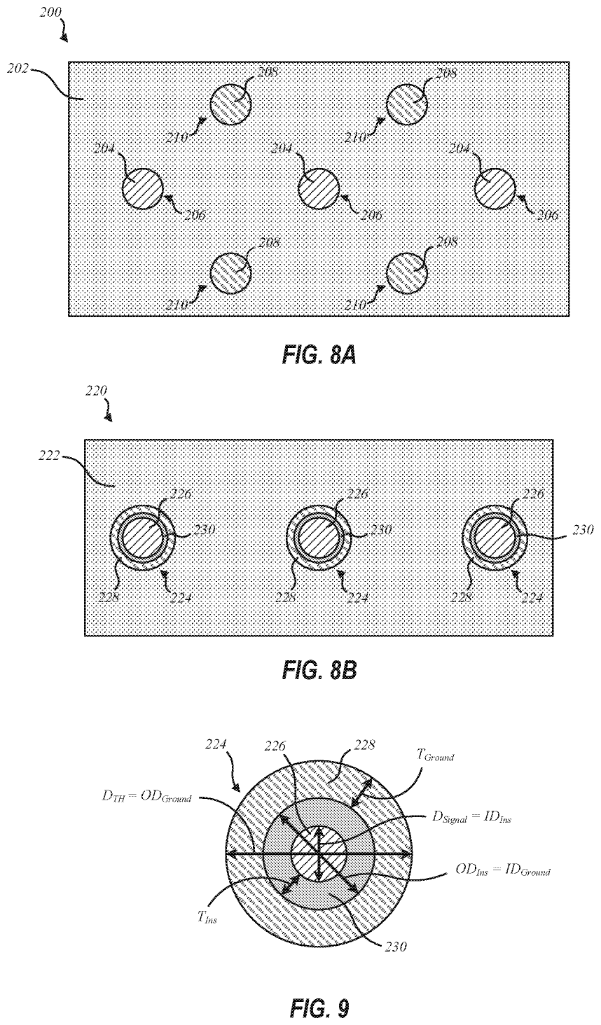

FIGS. 8A and 8B illustrate this advantage in the case of a single-ended interconnect array for a double data rate (DDR) memory device. FIG. 8A shows a conventional single-ended DDR interconnect array 200 in a substrate 202 wherein each interconnecting pathway has its own dedicated through hole, while FIG. 8B shows a comparative single-ended DDR interconnect array 220 where each through hole accommodates both a signal pathway and a ground pathway. The conventional single-ended DDR interconnect array 200 includes a pattern of interconnect pathways 204, 208. In the example configuration shown in FIG. 8A, the array 200 includes a plurality of signal pathways 204 each passing through a corresponding signal through hole 206 in the substrate 202. The array 200 also includes a corresponding number of ground pathways 208 each passing through a corresponding ground through hole 210 in the substrate 202, which provide for desired impedance matching and crosstalk management for the signals passing through the signal pathways 204. For ease of distinguishing between the signal pathways 204 and the ground pathways 208, the ground pathways 208 use the same cross-hatching pattern as was used for the first electrical pathway 14, 54 in the devices 10, 50 described with respect to FIGS. 1-4 (i.e., the first cross-hatching pattern with parallel cross-hatching lines extending from the top left toward the bottom right), while the signal pathways 204 use the same cross-hatching pattern as was used for the second electrical pathway 16, 56 (i.e., the second cross-hatching pattern with parallel cross-hatching lines extending from the top right toward the bottom left).

Turning to FIG. 8B, the comparative array 220 is formed in a substrate 222, which can be similar or identical to the substrate 202 for the array 200 of FIG. 8A. A plurality of through holes 224 are formed through the substrate 222 which allow interconnect pathways 226, 228 to form a conductive route from one side of the substrate 222 to the opposing side. As can be seen in FIG. 8B, within each through hole 224 is formed a signal pathway 226 (which, in the example of FIG. 8B is formed in an interior region of the through hole 224, e.g., proximate to a central axis of the through hole 224), a ground pathway 228 (which, in the example of FIG. 8B is formed in an exterior region of the through hole 224, e.g., proximate to a circumference of the through hole 224), and an insulation layer 230 located between and electrically separating and isolating the signal pathway 226 from its corresponding ground pathway 228. As can be seen by a comparison of FIGS. 8A and 8B, the array 220 that uses the multi-pathway configuration of the present disclosure (FIG. 8B) takes up a significantly smaller area of the substrate 222 then the conventional array 200 for the same number of signal pathways (i.e., three signal pathways 206 in the array 200 and three signal pathways 226 in the array 220) and wherein the size of each signal pathway is the same (i.e., the diameter of the signal pathways 206 in the conventional array 200 is the same as the diameter of the inner signal pathways 226 in the multi-pathway array 220).

The inventors have also discovered that it is possible to design the multi-pathway through holes 224 to have the same specified impedance target and crosstalk management as that which is provided in the conventional array 200 with the dispersed signal pathways 204 and ground pathways 208 in their own corresponding through holes 206, 210. The inventors have found that there is a balance between various parameters of the pathways 226, 228 and the insulation layer 230. For example, the inventors found that crosstalk mitigation benefits tend to come at the expense of impedance matching. In an example, the inventors balanced the size of the insulation layer 230, the dielectric constant Dₖ of the insulation material that forms the insulation layer 230, the size of the inner signal pathway 226, and in some examples, the size of the outer ground pathway 228 in order to achieve a specified target impedance. In the example of the coaxial and concentric signal pathway 226 and ground pathway 228 of FIG. 8B, the “size” of the various structures can be defined by the diameters of the circular structures that form the inner signal pathway 226, the middle insulation layer 230, and the outer ground pathway 228. FIG. 9 shows the relevant dimensions in such an example. The inner pathway 226 can be defined by its diameter D_{Signal}. The insulation layer 230 can be defined by its axial thickness T_{Ins}, which is equal to the difference between the outer diameter OD_{Ins} and the inner diameter ID_{Ins} of the insulation 230 (wherein the insulation layer inner diameter ID_{Ins} is equal to the diameter D_{Signal} of the inner signal pathway 226). The outer ground pathway 228 can be defined by its axial thickness T_{Ground}, which is equal to the difference between the outer diameter OD_{Ground} and the inner diameter ID_{Ground} of the ground pathway 226 (wherein the ground inner diameter ID_{Ground} is equal to the insulation outer diameter OD_{Ins} and the ground outer diameter OD_{Ground} is equal to the total diameter D_{TH} of the through hole 224).

In an example, the insulating material of the insulation layer 230 has a relatively low dielectric constant Dₖ so that the capacitance that may form between the signal pathway 226 and the ground pathway 228 due to their close proximity in the through hole 224 will be below a specified capacitance value. In an example, the dielectric constant Dₖ of the insulation layer 230 is no more than about 15, such as no more than about 14.5, for example no more than about 14, such as no more than about 13.5, such as no more than about 13, for example no more than about 12.5, such as no more than about 12, for example no more than about 11.5, such as no more than about 11, for example no more than about 10.5, such as no more than about 10, for example no more than about 9.5, such as no more than about 9, for example no more than about 8.5, such as no more than about 8, for example no more than about 7.5, such as no more than about 7, for example no more than about 6.5, such as no more than about 6, for example no more than about 5.5, such as no more than about 5, for example no more than about 4.5, such as no more than about 4, for example no more than about 3.5, such as no more than about 3, for example no more than about 2.5, such as no more than about 2. In an example, the capacitance that exists between the signal pathway 226 and the ground pathway 228 is no more than about 400 picofarads (pF), for example no more than about 350 pF, such as no more than about 300 pF, for example no more than about 250 pF, such as no more than about 200 pF, for example no more than about 15 pF, such as around 100 pF to 200 pF.

As noted above, the size of the insulation layer 230 (e.g., the insulation layer axial thickness T_{Ins}) and the size of the signal pathway 226 (e.g., the signal pathway diameter D_{Signal}) can be selected to achieve a specified impedance, e.g., for impedance matching between the signal pathway 226 and the ground pathway 228. In an example, the specified impedance can be from about 20 ohms (Ω) to about 60Ω, such as from about 30Ω to about 50Ω, for example from about 35Ω to about 45Ω, such as from about 40Ω to about 50Ω.

The inventors have found that to achieve a specified impedance that is within these ranges with the insulation material dielectric constants described above can be achieved with the signal pathway 226 having a diameter D_{Signal} of up to about 250 μm, such as up to about 100 μm, such as up to about 50 μm, for example up to about 40 μm, such as up to about 30 μm, and with the insulation layer 230 having an axial thickness T_{Ins} of up to about 50 μm, such as up to about 40 μm, for example up to about 30 μm, such as up to about 25 μm, for example up to about 20 μm, such as up to about 15 μm, for example up to about 10 μm. In an example, the outer ground pathway 228 can have an axial thickness T_{Ground} of up to about 50 μm, such as up to about 40 μm, for example up to about 30 μm, such as up to about 25 μm, for example up to about 20 μm, such as up to about 15 μm, for example up to about 10 μm. In an example, the through hole 224 has a total diameter D_{TH} of from about 50 μm to about 300 μm, such as from about 75 μm to about 275 μm, for example from about 90 μm to about 250 μm, such as about 100 μm.

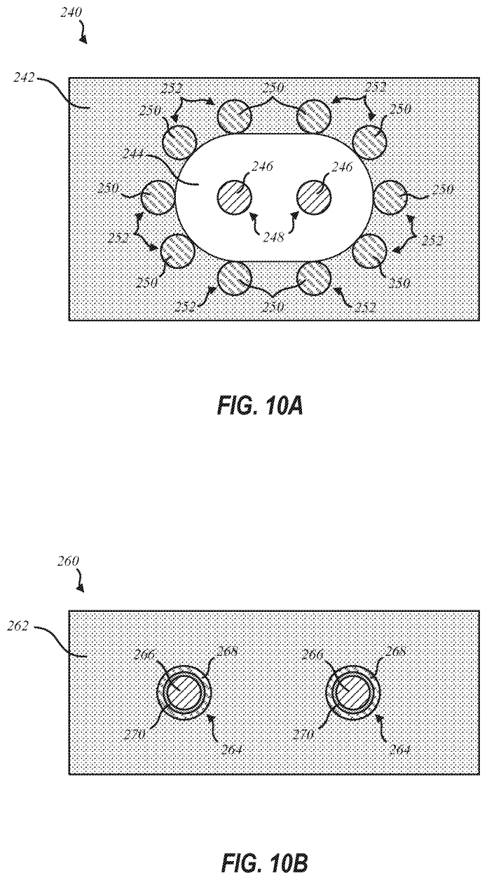

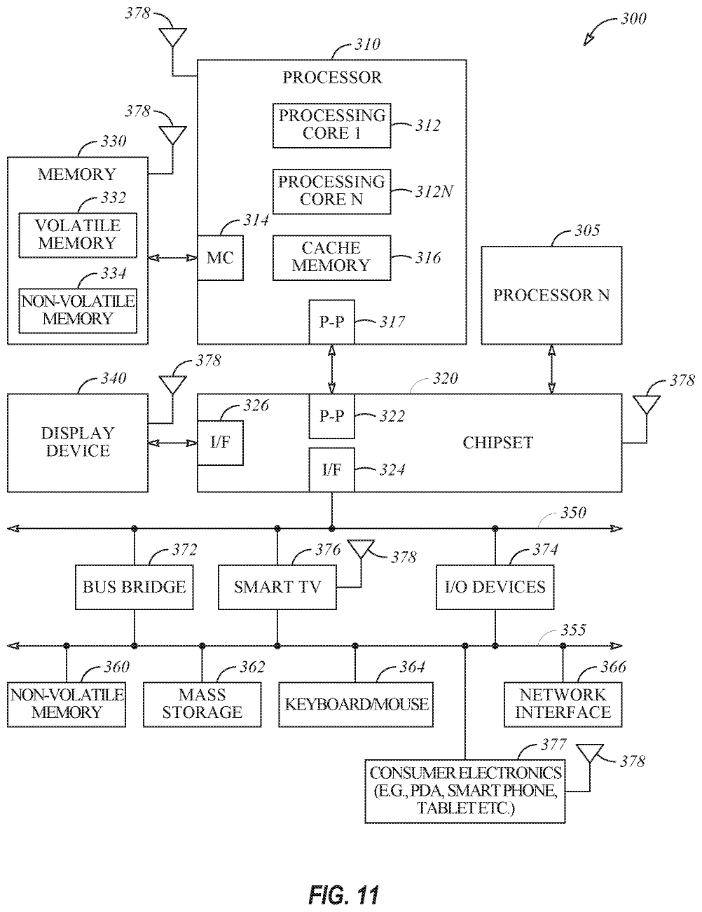

The use of multiple pathways in the same through hole can provide similar advantages for differential signaling applications. FIGS. 10A and 10B illustrate the comparison between conventional through-hole interconnect routing in a serializer/deserializer (SerDes), shown in FIG. 10A, and a comparative configuration using the multi-pathway through hole routing of the present disclosure, shown in FIG. 10B. In FIG. 10A, a conventional differential signal configuration 240 is shown through a substrate 242. The conventional configuration 240 includes a signal pad 244 on which are provided two separate signal pathways 246 each passing through its own dedicated signal through hole 248. A large array of ground pathways 250 surround the signal pad 244. Each ground pathway 250 passes through its own dedicated ground through hole 252.

Turning to FIG. 10B, the comparative differential configuration 260 is formed in a substrate 262, which can be similar or identical to the substrate 242 for the conventional configuration 240 of FIG. 10A. A pair of through holes 264 are formed through the substrate 262 which allow differential interconnect pathways 266, 268 to form a conductive route from one side of the substrate 262 to the opposing side. As can be seen in FIG. 10B, within each through hole 264 is formed a differential signal pathway 266 (which, in the example of FIG. 10B is formed in an interior region of the through hole 264, e.g., proximate to a central axis of the through hole 264), a differential ground pathway 268 (which, in the example of FIG. 10B is formed in an exterior region of the through hole 264, e.g., proximate to a circumference of the through hole 264), and an insulation layer 270 located between and electrically separating and isolating the differential signal pathway 266 from its corresponding differential ground pathway 268. As can be seen by a comparison of FIGS. 10A and 10B, the configuration 260 that uses the multi-pathway configuration of the present disclosure (FIG. 10B) takes up a significantly smaller area of the substrate 262 then the conventional configuration 240 for the same size of differential signal pathway (i.e., the differential signal pathways 246 in the conventional configuration 240 and the differential signal pathways 266 in the multi-pathway configuration 260 have the same diameter) and the multi-pathway configuration 266 of the present disclosure can be configured with the same impedance matching as the conventional configuration 240 (e.g., both the conventional configuration 240 and the multi-pathway configuration 260 can achieve an impedance of from about 70Ω to about 110Ω, such as from about 80Ω to about 100Ω, for example about 90Ω, which are common impedances for differential signaling such as in a SerDes device). In an example, a differential multi-pathway configuration 260 can include a diameter of the inner signal pathway 266 (e.g., similar to the diameter D_{Signal} in the structure of FIG. 9) of from about 10 μm to about 30 μm, such as about 20 μm, and an axial thickness of the insulation layer 270 (e.g., similar to the axial thickness T_{Ins} in the structure of FIG. 9) of from about 10 μm to about 25 μm, such as about 18 μm, and the dielectric constant Dₖ of the material that forms the insulation layer 270 can be no more than about 5, such as no more than about 2.

FIG. 11 illustrates a system level diagram, depicting an example of an electronic device (e.g., system) that may include multi-pathway interconnect routing through a common through hole described above. In one embodiment, the system 300 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 300 includes a system on a chip (SOC) system.

In one embodiment, processor 310 has one or more processor cores 312 and 312N, where 312N represents the Nth processor core inside processor 310 where N is a positive integer. In one embodiment, system 300 includes multiple processors including 310 and 305, where processor 305 has logic similar or identical to the logic of processor 310. In some embodiments, processing core 312 includes, but is not limited to, pre-fetch logic to fetch instructions, decode logic to decode the instructions, execution logic to execute instructions and the like. In some embodiments, processor 310 has a cache memory 316 to cache instructions and/or data for system 300. Cache memory 316 may be organized into a hierarchal structure including one or more levels of cache memory.

In some embodiments, processor 310 includes a memory controller 314, which is operable to perform functions that enable the processor 310 to access and communicate with memory 330 that includes a volatile memory 332 and/or a non-volatile memory 334. In some embodiments, processor 310 is coupled with memory 330 and chipset 320. Processor 310 may also be coupled to a wireless antenna 378 to communicate with any device configured to transmit and/or receive wireless signals. In one embodiment, an interface for wireless antenna 378 operates in accordance with, but is not limited to, the IEEE 802.11 standard and its related family. Home Plug AV (HPAV), Ultra-Wide Band (UWB), Bluetooth, WiMax, or any form of wireless communication protocol.

In some embodiments, volatile memory 332 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 334 includes, but is not limited to, flash memory, phase change memory (PCM), read-only memory (ROM), electrically erasable programmable read-only memory (EEPROM), or any other type of non-volatile memory device.

Memory 330 stores information and instructions to be executed by processor 310. In one embodiment, memory 330 may also stores temporary variables or other intermediate information while processor 310 is executing instructions. In the illustrated embodiment, chipset 320 connects with processor 310 via Point-to-Point (PtP or P-P) interfaces 317 and 322. Chipset 320 enables processor 310 to connect to other elements in system 300. In some embodiments of the example system, interfaces 317 and 322 operate in accordance with a PtP communication protocol such as the Intel® QuickPath Interconnect (QPI) or the like. In other embodiments, a different interconnect may be used.

In some embodiments, chipset 320 is operable to communicate with processor 310, 305N, display device 340, and other devices, including a bus bridge 372, a smart TV 376, I/O devices 374, nonvolatile memory 360, a storage medium 362 (such as one or more mass storage devices), a keyboard/mouse 364, a network interface 366, and various forms of consumer electronics 377 (such as a PDA, smart phone, tablet etc.), etc. In one embodiment, chipset 320 couples with these devices through an interface 324. Chipset 320 may also be coupled to a wireless antenna 378 to communicate with any device configured to transmit and/or receive wireless signals. In one example, any combination of components in a chipset may be separated by a continuous flexible shield as described in the present disclosure.

Chipset 320 connects to display device 340 via interface 326. Display device 340 may be, for example, a liquid crystal display (LCD), a light emitting diode (LED) array, an organic light emitting diode (OLED) array, or any other form of visual display device. In some embodiments of the example system, processor 310 and chipset 320 are merged into a single SOC. In addition, chipset 320 connects to one or more buses 350 and 355 that interconnect various system elements, such as I/O devices 374, nonvolatile memory 360, storage medium 362, a keyboard/mouse 364, and network interface 366. Buses 350 and 355 may be interconnected together via a bus bridge 372.

In one embodiment, mass storage device 362 includes, but is not limited to, a solid state drive, a hard disk drive, a universal serial bus flash memory drive, or any other form of computer data storage medium. In one embodiment, network interface 366 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 11 are depicted as separate blocks within the system 300, the functions performed by some of these blocks may be integrated within a single semiconductor circuit or may be implemented using two or more separate integrated circuits. For example, although cache memory 316 is depicted as a separate block within processor 310, cache memory 316 (or selected aspects of 316) can be incorporated into processor core 312.

To better illustrate the methods and apparatuses disclosed herein, a non-limiting list of exemplary embodiments are provided here:

EMBODIMENT 1 can include subject matter (such as an apparatus, a device, a method, or one or more means for performing acts), such as can include an electronic device comprising a substrate comprising a first side and an opposing second side, a through hole passing through the substrate between the first side and the second side, a first electrical pathway passing from a first position on the first side of the substrate, through a first portion of the through hole, to a first corresponding position on the second side of the substrate, a second electrical pathway passing from a second position on the first side of the substrate, through a second portion of the through hole, to a corresponding second position on the second side of the substrate, and an insulation layer between the first electrical pathway and the second electrical pathway within the through hole, wherein the insulation layer electrically isolates the first electrical pathway from the second electrical pathway.

EMBODIMENT 2 can include, or can optionally be combined with the subject matter of EMBODIMENT 1, to optionally include the first electrical pathway being configured to carry an electrical signal from the first side to the second side of the substrate or to act as a ground between the first side and the second side of the substrate or to carry electrical power from the first side to the second side of the substrate.

EMBODIMENT 3 can include, or can optionally be combined with the subject matter of one or a combination of EMBODIMENT 1 and EMBODIMENT 2, to optionally include the second electrical pathway being configured to carry an electrical signal from the first side to the second side of the substrate or to act as a ground between the first side and the second side of the substrate or to carry electrical power from the first side to the second side of the substrate.

EMBODIMENT 4 can include, or can optionally be combined with the subject matter of one or any combination of EMBODIMENTS 1-3, to optionally include the first electrical pathway being configured to carry an electrical signal from the first side to the second side of the substrate and the second electrical pathway being configured as an electrical ground between the first side and the second side of the substrate.

EMBODIMENT 5 can include, or can optionally be combined with the subject matter of one or any combination of EMBODIMENTS 1-4, to optionally include the first electrical pathway covering at least a portion of an interior bore surface of the through hole.

EMBODIMENT 6 can include, or can optionally be combined with the subject matter of one or any combination of EMBODIMENTS 1-5, to optionally include the second electrical pathway covering at least a portion of an interior bore surface of the through hole.

EMBODIMENT 7 can include, or can optionally be combined with the subject matter of one or any combination of EMBODIMENTS 1-6, to optionally include the first portion of the through hole, the second portion of the through hole, and the insulation layer within the through hole being coaxial and concentric.

EMBODIMENT 8 can include, or can optionally be combined with the subject matter of EMBODIMENT 7, to optionally include the first portion of the through hole being proximate to a central axis of the through hole and the second portion of the through hole being proximate to an outer circumference of the through hole.

EMBODIMENT 9 can include, or can optionally be combined with the subject matter of EMBODIMENT 7, to optionally include the second portion of the through hole being proximate to a central axis of the through hole and the first portion of the through hole being proximate to an outer circumference of the through hole.

EMBODIMENT 10 can include, or can optionally be combined with the subject matter of one or any combination of EMBODIMENTS 1-9, to optionally include a diameter of the first portion of the through hole being from about 10 micrometers to about 40 micrometers.

EMBODIMENT 11 can include, or can optionally be combined with the subject matter of one or any combination of EMBODIMENTS 1-10, to optionally include an axial thickness of the insulation layer being from about 5 micrometers to about 40 micrometers.

EMBODIMENT 12 can include, or can optionally be combined with the subject matter of one or any combination of EMBODIMENTS 1-11, to optionally include the through hole having a total diameter of from about 50 micrometers to about 150 micrometers.

EMBODIMENT 13 can include, or can optionally be combined with the subject matter of one or any combination of EMBODIMENTS 1-12, to optionally include the insulation layer covering at least a portion of the first electrical pathway on the first side of the substrate

EMBODIMENT 14 can include, or can optionally be combined with the subject matter of one or any combination of EMBODIMENTS 1-13, to optionally include a first build-up layer deposited over at least a portion of the first electrical pathway, over at least a portion of the second electrical pathway, or over at least a portion of the first electrical pathway and over at least a portion of the second electrical pathway on the first side of the substrate.

EMBODIMENT 15 can include, or can optionally be combined with the subject matter of EMBODIMENT 14, to optionally include a first via through the first build-up layer that exposes an outer surface of the first electrical pathway on the first side of the substrate.

EMBODIMENT 16 can include, or can optionally be combined with the subject matter of one or a combination of EMBODIMENT 14 and EMBODIMENT 15, to optionally include a second via through the first build-up layer that exposes an outer surface of the second electrical pathway on the first side of the substrate.

EMBODIMENT 17 can include, or can optionally be combined with the subject matter of one or any combination of EMBODIMENTS 14-16, to optionally include a second build-up layer deposited over at least a portion of the first electrical pathway, over at least a portion of the second electrical pathway, or over at least a portion of the first electrical pathway and over at least a portion of the second electrical pathway on the second side of the substrate.

EMBODIMENT 18 can include, or can optionally be combined with the subject matter of EMBODIMENT 17, to optionally include a third via through the second build-up layer that exposes an outer surface of the first electrical pathway on the second side of the substrate.

EMBODIMENT 19 can include, or can optionally be combined with the subject matter of one or a combination of EMBODIMENT 17 and EMBODIMENT 18, to optionally include a fourth via through the second build-up layer that exposes an outer surface of the second electrical pathway on the second side.

EMBODIMENT 20 can include, or can optionally be combined with the subject matter of one or any combination of EMBODIMENTS 1-19, to optionally include the insulation layer comprising silicon nitride (SiNx), silicon oxynitride (SiOₓN_{y}), silicon dioxide (SiO₂), a carbon-doped oxide (CDO), an organic dielectric, an organic polymer, a fluorine-doped silicon dioxide, or combinations thereof.

EMBODIMENT 21 can include, or can optionally be combined with the subject matter of one or any combination of EMBODIMENTS 1-20, to include subject matter (such as an apparatus, a device, a method, or one or more means for performing acts), such as can include a method of manufacturing an electronic device, the method comprising providing or receiving a substrate, the substrate including a first side, an opposing second side, and a through hole passing through the substrate from the first side to the second side, depositing a first conductive material onto the substrate to form a first electrical pathway, wherein the first electrical pathway passes from a first position on the first side of the substrate, through a first portion of the through hole, to a first corresponding position on the second side of the substrate, depositing a first insulating material in contact with the first electrical pathway to form a first insulation layer that electrically isolates the first electrical pathway from a second portion of the through hole, and depositing a second conductive material onto the substrate to form a second electrical pathway, wherein the second electrical pathway passes from a second position on the first side of the substrate, through the second portion of the through hole, to a corresponding second position on the second side of the substrate

EMBODIMENT 22 can include, or can optionally be combined with the subject matter of EMBODIMENT 21, to optionally include depositing a second insulating material onto at least a portion of the second electrical pathway.

EMBODIMENT 23 can include, or can optionally be combined with the subject matter of either one or a combination of EMBODIMENT 21 and EMBODIMENT 22, to optionally include depositing a first build-up layer onto at least a portion of the first electrical pathway on the first side of the substrate, or onto at least a portion of the second electrical pathway on the first side of the substrate, or onto at least a portion of the first electrical pathway and onto at least a portion of the second electrical pathway on the first side of the substrate.

EMBODIMENT 24 can include, or can optionally be combined with the subject matter of EMBODIMENT 23, to optionally include forming a first via through the first build-up layer to provide a first electrical connection to the first electrical pathway on the first side of the substrate.

EMBODIMENT 25 can include, or can optionally be combined with the subject matter of either one or a combination of EMBODIMENT 23 and EMBODIMENT 24, to optionally include forming a second via through the first build-up layer to provide a second electrical connection to the second electrical pathway of the first side of the substrate.

EMBODIMENT 26 can include, or can optionally be combined with the subject matter of one or any combination of EMBODIMENTS 23-25, to optionally include depositing a second build-up layer onto at least a portion of the first electrical pathway on the second side of the substrate, or onto at least a portion of the second electrical pathway on the second side of the substrate, or onto at least a portion of the first electrical pathway and onto at least a portion of the second electrical pathway on the second side of the substrate.

EMBODIMENT 27 can include, or can optionally be combined with the subject matter of EMBODIMENT 26, to optionally include forming a third via through the second build-up layer to provide a third electrical connection to the first electrical pathway on the second side of the substrate.

EMBODIMENT 28 can include, or can optionally be combined with the subject matter of either one or a combination of EMBODIMENT 26 and EMBODIMENT 27, to optionally include forming a fourth via through the second build-up layer to provide a fourth electrical connection to the second electrical pathway of the second side of the substrate.

EMBODIMENT 29 can include, or can optionally be combined with the subject matter of one or any combination of EMBODIMENTS 21-28, to optionally include the step of depositing the first conductive material to form the first electrical pathway comprising forming a first resist in a first specified pattern, depositing the first conductive material onto portions exposed by the first resist, and removing the first resist.

EMBODIMENT 30 can include, or can optionally be combined with the subject matter of one or any combination of EMBODIMENTS 21-29, to optionally include the step of depositing the second conductive material to form the second electrical pathway comprising forming a second resist in a second specified pattern, onto portions exposed by the second resist, and removing the second resist.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An electronic device comprising:
a substrate layer comprising a first side and an opposing second side;
a through hole passing through the substrate layer between the first side and the second side;
a first electrical pathway passing from a first position on the first side of the substrate layer, through a first portion of the through hole, to a first corresponding position on the second side of the substrate layer;
a second electrical pathway passing from a second position on the first side of the substrate layer, through a second portion of the through hole, to a corresponding second position on the second side of the substrate layer; and
an insulation layer between the first electrical pathway and the second electrical pathway within the through hole, wherein the insulation layer electrically isolates the first electrical pathway from the second electrical pathway.

2. The electronic device of claim 1, wherein the first electrical pathway and the second electrical pathway are each configured to carry an electrical signal from the first side to the second side of the substrate layer or to act as a ground between the first side and the second side of the substrate layer or are configured to carry electrical power from the first side to the second side of the substrate layer.

3. The electronic device of claim 1, wherein the first electrical pathway is configured to carry an electrical signal from the first side to the second side of the substrate layer and the second electrical pathway is configured as an electrical ground between the first side and the second side of the substrate layer.

4. The electronic device of claim 1, wherein the first electrical pathway covers at least a portion of an interior bore surface of the through hole.

5. The electronic device of claim 1, wherein the first portion of the through hole, the second portion of the through hole, and the insulation layer within the through hole are coaxial and concentric.

6. The electronic device of claim 5, wherein the first portion of the through hole is proximate to a central axis of the through hole and the second portion of the through hole is proximate to an outer circumference of the through hole.

7. The electronic device of claim 6, wherein a diameter of the first portion of the through hole is from about 10 micrometers to about 40 micrometers.

8. The electronic device of claim 6, wherein an axial thickness of the insulation layer is from about 5 micrometers to about 40 micrometers.

9. The electronic device of claim 6, wherein the through hole has a total diameter of from about 50 micrometers to about 150 micrometers.

10. The electronic device of claim 1, wherein the insulation layer covers at least a portion of the first electrical pathway on the first side of the substrate layer.

11. The electronic device of claim 1, further comprising a second insulation layer covering at least a portion of the second electrical pathway on the first side of the substrate layer.

12. The electronic device of claim 1, further comprising a build-up layer deposited over at least a portion of the first electrical pathway, over at least a portion of the second electrical pathway, or over at least a portion of the first electrical pathway and over at least a portion of the second electrical pathway on the first side of the substrate layer.

13. The electronic device of claim 12, further comprising a via through the build-up layer that exposes an outer surface of the first electrical pathway or of the second electrical pathway.

14. The electronic device of claim 1, wherein the insulation layer comprises silicon and nitrogen.

15. An electronic package comprising:
a package substrate;
a semiconductor die coupled to the package substrate, the semiconductor die comprising:
a substrate layer comprising a first side and an opposing second side;
a through hole passing through the substrate layer between the first side and the second side;
a first electrical pathway passing from a first position on the first side of the substrate layer, through a first portion of the through hole, to a first corresponding position on the second side of the substrate layer;
a second electrical pathway passing from a second position on the first side of the substrate layer, through a second portion of the through hole, to a corresponding second position on the second side of the substrate layer; and
an insulation layer between the first electrical pathway and the second electrical pathway within the through hole, wherein the insulation layer electrically isolates the first electrical pathway from the second electrical pathway

16. The electronic package of claim 15, wherein the first electrical pathway is configured to carry an electrical signal from the first side to the second side of the substrate layer and the second electrical pathway is configured as an electrical ground between the first side and the second side of the substrate layer.

17. The electronic package of claim 15, wherein the first portion of the through hole, the second portion of the through hole, and the insulation layer within the through hole are coaxial and concentric.

18. The electronic package of claim 15, wherein the semiconductor die further comprises a second insulation layer covering at least a portion of the second electrical pathway on the first side of the substrate layer.

19. The electronic package of claim 15, wherein the insulation layer comprises silicon and nitrogen.

20. A method comprising the steps of:
providing or receiving a substrate layer, the substrate layer including a first side, an opposing second side, and a through hole passing through the substrate layer from the first side to the second side;
depositing a first conductive material onto the substrate layer to form a first electrical pathway, wherein the first electrical pathway passes from a first position on the first side of the substrate layer, through a first portion of the through hole, to a first corresponding position on the second side of the substrate layer;
depositing a first insulating material in contact with the first electrical pathway to form a first insulation layer that electrically isolates the first electrical pathway from a second portion of the through hole; and
depositing a second conductive material onto the substrate layer to form a second electrical pathway, wherein the second electrical pathway passes from a second position on the first side of the substrate layer, through the second portion of the through hole, to a corresponding second position on the second side of the substrate layer.

21. The method of claim 20, further comprising depositing a second insulating material onto at least a portion of the second electrical pathway.

22. The method of claim 20, further comprising depositing a build-up layer onto at least a portion of the first electrical pathway on the first side of the substrate layer, or onto at least a portion of the second electrical pathway on the first side of the substrate layer, or onto at least a portion of the first electrical pathway and onto at least a portion of the second electrical pathway on the first side of the substrate layer.

23. The method of claim 20, further comprising forming a first via through the build-up layer to provide a first electrical connection to the first electrical pathway, or a second via through the build-up layer to provide a second electrical connection to the second electrical pathway, or both.

24. The method of claim 20, wherein depositing the first conductive material to form the first electrical pathway comprises forming a first resist in a first specified pattern, depositing the first conductive material onto portions exposed by the first resist, and removing the first resist.

25. The method of claim 20, wherein depositing the second conductive material to form the second electrical pathway comprises forming a second resist in a second specified pattern, onto portions exposed by the second resist, and removing the second resist.

26. The method of claim 20, further comprising electrically coupling the substrate layer to a package substrate.
